(19) United States
(12) Patent Application Publication
(10) Pub. No.: US 2026/0047344 A1
(43) Pub. Date: Feb. 12, 2026

(54) SPIN ORBIT TORQUE (SOT) DEVICE WITH FERROMAGNETIC SOT CHANNEL AND ANTIFERROMAGNET

(71) Applicant: Everspin Technologies, Inc., Chandler, AZ (US)

(72) Inventors: Sumio IKEGAWA, Phoenix, AZ (US); Kerry Joseph NAGEL, Scottsdale, AZ (US); Monika ARORA, Chandler, AZ (US); Sanjeev AGGARWAL, Scottsdale, AZ (US)

(73) Assignee: Everspin Technologies, Inc., Chandler, AZ (US)

(21) Appl. No.: 18/795,509

(22) Filed: Aug. 6, 2024

(51) Int. Cl. H10N 50/10; H10B 61/00; H10N 50/01; H10N 50/85

(52) U.S. Cl. CPC H10N 50/10; H10B 61/00; H10N 50/01; H10N 50/85

(57) ABSTRACT

A memory includes a plurality of magnetoresistive devices, wherein each magnetoresistive device includes a fixed magnetic layer, a free magnetic layer, a tunnel barrier disposed between the fixed and free magnetic layers, and an insertion layer disposed below the free magnetic layer, wherein the fixed magnetic layer is formed above the free magnetic layer. The memory also includes a plurality of antiferromagnetic layers, wherein each antiferromagnetic layer is disposed above a seed layer. The memory further includes a spin-orbit-torque (SOT) channel, wherein the SOT channel is disposed between the plurality of magnetoresistive devices and the plurality of antiferromagnetic layers.

### TECHNICAL FIELD

The present disclosure relates to, among other things, magnetoresistive stacks and methods for fabricating and using the disclosed magnetoresistive stacks.

### INTRODUCTION

Spin-orbit-torque (SOT) magnetoresistive random access memory (MRAM) devices store information by controlling the resistance across a magnetic tunnel junction (MTJ) such that a read current through the MTJ results in a voltage drop having a magnitude that is based on the state of the MTJ stack. The resistance in an MTJ stack can be varied based on the relative magnetic states of the magnetoresistive layers within the MTJ stack. In such memory devices, there is typically a portion of the MTJ stack that has a fixed magnetic state (i.e., fixed region) and another portion that has a free magnetic state (i.e., free region) that is controlled to be in either of two possible states relative to the portion having the fixed magnetic state. Because the resistance through the MTJ stack changes based on the orientation (i.e., magnetization direction) of the free region relative to the fixed region, information can be stored in the MTJ by setting the orientation of the free region. The information may be later retrieved by sensing a resistance of the MTJ stack.

### BRIEF DESCRIPTION OF THE DRAWINGS

Embodiments of the present disclosure may be implemented in connection with aspects illustrated in the attached drawings. These drawings show different aspects of the present disclosure and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure and/or manner of construction of the various described embodiments, as well as associated methods of manufacture. For ease of illustration, the figures depict the different regions along the thickness of the illustrated stacks as a layer having well-defined boundaries with straight edges (e.g., depicted using lines). However, one skilled in the art would understand that, in reality, at an interface between adjacent regions or layers, the materials of these regions may alloy together, or migrate into one or the other material, and make their boundaries ill-defined or diffuse. That is, although multiple layers with distinct interfaces are illustrated in the figures, in some cases, over time and/or due to exposure to high temperatures, materials of some of the layers may migrate into or interact with materials of other layers to present a more diffuse interface between these layers. Further, although the figures illustrate each region or layer as having a relatively uniform thickness across its width, one of ordinary skill in the art would recognize that, in reality, the different regions may have a non-uniform thickness (e.g., the thickness of a layer may vary along the width of the layer), and/or the thickness of one region or layer may differ relative to the thickness of another (e.g., adjacent) region or layer.

In the figures and description, details of well-known features (e.g., interconnects, etc.) and manufacturing techniques (e.g., deposition techniques, etching techniques, etc.) may be omitted for the sake of brevity (and to avoid obscuring other features and details), since these features/techniques are well-known to those of ordinary skill in the art. Elements in the figures are not necessarily drawn to scale. The dimensions of some features may be exaggerated relative to other features to improve understanding of the exemplary embodiments. Cross-sectional views are simplifications provided to help illustrate the relative positioning of various regions/layers and to describe various processing steps. One skilled in the art would appreciate that the cross-sectional views are not drawn to scale and should not be viewed as representing proportional relationships between different regions/layers. Moreover, while certain regions/layers and features are illustrated with straight 90-degree edges, in reality, such regions/layers may be more “rounded” and/or gradually sloping. It should also be noted that, even if it is not specifically mentioned, aspects described with reference to one embodiment may also be applicable to, and may be used with, other embodiments.

Moreover, there are many embodiments described and illustrated herein. The present disclosure is neither limited to any single aspect nor embodiment thereof, nor to any combinations and/or permutations of such aspects and/or embodiments. Moreover, each aspect of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein. Notably, an embodiment or implementation described herein as “exemplary” is not to be construed as preferred or advantageous, for example, over other embodiments or implementations. Rather, it is intended to reflect or indicate the embodiment(s) is/are “example” embodiment(s). Further, even though the figures and this written disclosure appear to describe the disclosed magnetoresistive stacks in a particular order of construction (e.g., from bottom to top), it is understood that the depicted magnetoresistive stacks may have a different order (e.g., the opposite order (e.g., from top to bottom)).

FIG. 1 depicts an exemplary spin-orbit-torque (SOT) magnetoresistive random access memory (MRAM) device.

FIG. 2 depicts an exemplary SOT MRAM device, according to one or more embodiments.

FIG. 3 depicts an exemplary SOT MRAM device and dimensions, according to one or more embodiments.

FIG. 4 depicts a flow diagram for manufacturing an exemplary SOT MRAM device, according to one or more embodiments.

FIG. 5 depicts an exemplary SOT MRAM device, according to one or more embodiments.

FIGS. 6A and 6B depict exemplary SOT MRAM devices, according to one or more embodiments.

FIG. 7 depicts a flow diagram for manufacturing an exemplary SOT MRAM device, according to one or more embodiments.

FIG. 8 depicts an exemplary SOT MRAM device, according to one or more embodiments.

FIG. 9 depicts a flow diagram for manufacturing an exemplary SOT MRAM device, according to one or more embodiments.

### DETAILED DESCRIPTION OF EMBODIMENTS

It should be noted that all numeric values disclosed herein (including all disclosed thickness values, limits, and ranges) may have a variation of ±10% (unless a different variation is specified) from the disclosed numeric value. For example, a layer disclosed as being “t” units thick can vary in thickness from (t−0.1t) to (t+0.1t) units. Further, all relative terms such as “about,” “substantially,” “approximately,” etc. are used to indicate a possible variation of ±10% (unless noted otherwise or another variation is specified). Moreover, in the claims, values, limits, and/or ranges of the thickness and atomic composition of, for example, the described layers/regions, mean the value, limit, and/or range±10%. It should be noted that the exemplary thickness values discussed in this disclosure are expected values (e.g., not measured values) of layer thicknesses immediately after deposition (based on deposition conditions, etc.). As a person of ordinary skill in the art would recognize, these as-deposited thickness values of a layer or region may change (e.g., by inter-layer diffusion, etc.) after further processing (e.g., exposure to high temperatures, etc.).

Unless defined otherwise, all terms of art, notations and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein are incorporated by reference in their entirety. If a definition or description set forth in this disclosure is contrary to, or otherwise inconsistent with, a definition and/or description in these references, the definition and/or description set forth in this disclosure prevails over those in the references that are incorporated herein by reference. None of the references described or referenced herein is admitted to be prior art to the current disclosure.

It should be noted that the description set forth herein is merely illustrative in nature and is not intended to limit the embodiments of the subject matter, or the application and uses of such embodiments. Any implementation described herein as exemplary is not to be construed as preferred or advantageous over other implementations. Rather, the term “exemplary” is used in the sense of example or “illustrative,” rather than “ideal.” The terms “comprise,” “include,” “have,” “with,” and any variations thereof are used synonymously to denote or describe a non-exclusive inclusion. As such, a device or a method that uses such terms does not include only those elements or steps but may include other elements and steps not expressly listed or inherent to such device and method. Further, the terms “first,” “second,” and the like, herein do not denote any order, quantity, or importance, but rather are used to distinguish one element from another. Similarly, terms of relative orientation, such as “top,” “bottom,” “left,” “right,” etc. are used with reference to the orientation of the structure(s) illustrated in the figures being described. Moreover, the terms “a” and “an” herein do not denote a limitation of quantity, but rather denote the presence of at least one of the referenced items.

In this disclosure, the term “region” is used generally to refer to one or more layers of material. That is, a region (as used herein) may include a single layer (or film or coating) of material or multiple layers or coatings (or films) of materials stacked one on top of another to form a multi-layer system/structure. Further, although in the description below, the different regions in the disclosed stack are sometimes referred to by specific names (such as, e.g., free region, fixed region, intermediate region, top electrode layer, etc.), this is only for ease of description and not intended as a functional description of the layer. Moreover, although the description below and the figures appear to depict a certain orientation of the layers relative to each other, those of ordinary skill in the art will understand that such descriptions and depictions are only exemplary. For example, though the free region is depicted as being “below” an intermediate region, in some aspects the entire magnetoresistive stack may be flipped such that the intermediate region is “below” the free region.

In one exemplary aspect, the magnetoresistive stack of the present disclosure may be implemented as an SOT MRAM element (“memory element”). In such aspects, the magnetoresistive stack may include an intermediate region positioned (or sandwiched) between two ferromagnetic regions to form an MTJ device (or an MTJ-type device). In MTJ devices, the intermediate region may be a tunnel barrier and may include an insulating material, such as, e.g., a dielectric material. The intermediate layers may include now-known or future-developed electrically insulating materials (including, e.g., oxides, nitrides, carbonitrides, etc.).

Of the two ferromagnetic regions disposed on either side of the intermediate region, one ferromagnetic region may be a magnetically “fixed” (or “pinned”) region, and the other ferromagnetic region may be a magnetically “free” region. The term “free” is intended to refer to ferromagnetic regions having a magnetization vector that may change or move significantly in response to applied magnetic fields, spin-polarized currents, or spin currents used to switch the magnetization vector. On the other hand, the words “fixed” and “pinned” are used to refer to ferromagnetic regions having a magnetization vector that does not move substantially in response to such applied magnetic fields or spin-polarized currents.

The direction of the magnetization vectors (e.g., magnetization direction) of the free region may be switched and/or programmed (for example, through spin-transfer-torque (STT), spin-orbit-torque (SOT), or a magnetic field generated by electrical current passing through a nearby conductor) by application of a write signal (e.g., one or more current pulses) to the magnetoresistive memory stack. As is known in the art, an electrical resistance of the described magnetoresistive stack may change based on whether the magnetization direction (e.g., the direction of the magnetic moment) of the free region adjacent to the non-magnetic layer is in a parallel alignment (P) or in an antiparallel alignment (AP) with the magnetization direction (e.g., the direction of the magnetic moment) of the fixed region adjacent to the non-magnetic layer. Typically, if the two regions have the same magnetization alignment (e.g., in the P magnetic state), the resulting relatively low(er) resistance (R_{L}) is considered as a digital “0,” while if the alignment is antiparallel (e.g., in the AP magnetic state) the resulting relatively high(er) resistance (R_{H}) is considered to be a digital “1.” A memory device (such as an MRAM) may include multiple such magnetoresistive stacks, which may be referred to as memory cells or elements, arranged in an array of columns and rows. By measuring the current through each cell, the resistance of each cell, and thus the data stored in the memory array can be “read.”

Magnetoresistance ratio (MR) is the ratio of the change in resistance of a magnetoresistive stack between its high and low resistance states (MR=(R_{H}−R_{L})/R_{L}, where R_{L} and R_{H} are the resistance of the magnetoresistive stack in the low and high resistance states, respectively. MR is indicative of the strength of the signal when a memory element is “read.” For an MTJ-type magnetoresistive stack with a strong read signal, a larger MR (e.g., a larger difference between the individual resistances R_{H} and R_{L}) is desirable. When the intermediate layer of magnetoresistive stack is a tunnel barrier made of a dielectric material, the resistance may be measured by the resistance-area product (RA).

In a magnetoresistive device utilizing SOT switching mechanics, switching the magnetization of the free region of a magnetoresistive stack may be accomplished by driving a current pulse through a spin Hall (SH) material proximate (e.g., in contact with or near) the free region. The polarity of the current pulse and the characteristics (e.g., positive or negative spin Hall angle) of the SH material determine the direction in which the magnetic moment of the free region is disposed. SH material may have a positive spin Hall angle or a negative spin Hall angle. SH materials with positive spin Hall angle may be referred to herein as positive SH materials, while SH materials with negative spin Hall angle may be referred to herein as negative SH materials. The terms “positive” and “negative” as used in this context are relative terms only, where the term “positive” indicates the material causes, e.g., a clockwise spin magnetization direction at the surface of the SH material relative to the direction of the current pulse passing through the SH material, and the term “negative” indicates the material causes, e.g., a counter-clockwise spin magnetization direction at the surface of the SH material relative to the direction of the current pulse through the SH material. In both positive and negative SH materials, spin current direction is perpendicular to the current pulse passing through the SH material. Examples of SH materials include, but are not limited to, platinum (Pt), tungsten (W), beta-tungsten (β-W), tantalum (Ta), palladium (Pd), hafnium (Hf), gold (Au), alloys including gold (e.g., AuPt, AuCu, AuW), alloys including bismuth (Bi) and selenium (Se) (e.g., Bi₂Se₃ or (BiSe)₂Te₃), alloys including bismuth (Bi) and antimony (Sb) (e.g., BiₓSb₁₋ₓ), alloys including platinum (Pt) and one or more of hafnium (Hf), aluminum (Al), or iron (Fe) (e.g., PtHf alloys, PtAl alloys, PtFe alloys), alloys including copper (Cu) and one or more of platinum (Pt), bismuth (Bi), iridium (Ir), or lead (Pb) (e.g., CuPt alloys, CuBi alloys, CuIr alloys, CuPb alloys), alloys including silver (Ag) and bismuth (Bi) (e.g., AgBi alloys), alloys including manganese (Mn) and one or more of platinum (Pt), iridium (Ir), palladium (Pd), iron (Fe) (e.g., PtMn alloys, IrMn alloys, PdMn alloys, FeMn alloys), Ta—Nb—Hf—Zr—Ti alloy, or combinations thereof. In one or more embodiments, platinum (Pt), palladium (Pd), gold (Au), alloys including bismuth (Bi) and selenium (Se), alloys including bismuth (Bi) and antimony (Sb), CuIr alloys, and CuPt alloys may act as a positive SH material, while beta-tungsten (β-W), tantalum (Ta), hafnium (Hf), CuBi alloys, CuPb alloys, Ta—Nb—Hf—Zr—Ti alloy, and alloys including silver (Ag) and bismuth (Bi) alloys may act as a negative SH material. In some embodiments, an SH material may act as either a positive SH material or a negative SH material depending on the mode and manner of deposition.

The mean current required to be passed through a free region in STT switching or through a SH material in SOT switching in order to change its magnetic state may be referred to as the critical current (Ic). The critical current is indicative of the current required to “write” data in a magnetoresistive memory cell. Typically, to write data, a write current (Iw) having a magnitude greater than (or equal to) Ic is directed to the MTJ bit to change the MTJ bit from P to AP (or AP to P based on the polarity of the current). Reducing the critical current is desirable so that, among other things, a smaller access transistor can be used for each memory cell and that a higher density, lower cost memory can be produced. A reduced critical current may also lead to greater longevity and/or durability of a magnetoresistive memory cell.

Embodiments described herein may utilize what may be referred to as spin-orbit torque to switch or aid in switching the magnetic state of the free region in an MTJ or MTJ-like device, where such an MTJ device is often included in a memory cell in a magnetic memory. A charge current through a conductor, e.g., an SH material, referred to as an SOT channel, adjacent to (and/or in contact with) the free region results in a spin torque acting on the free region due to the injection of a spin current into the free region from the spin-dependent scattering of electrons or spin-orbit interaction in the conductor, e.g., an SH material. This may be referred to as a spin Hall effect. The spin current is injected into the free region in a direction perpendicular to the boundary (or interface) where the free region and the SH material meet, and orthogonal to the direction of the charge current flow. The spin torque applied to the free region by the spin current impacts the magnetic state of the free region in a manner similar to spin-polarized tunneling current that flows through the MTJ in traditional spin-torque or STT magnetic tunnel junctions. There is an additional mechanism which may give rise to spin-orbit torque. If a charge current flows parallel to an interface between the free region and the SH material, the flowing electrons become spin polarized at the interface due to spin-orbit coupling. The polarized electrons exert a torque on the magnetization of the free region. This may be referred as a Rashba-Edelstein effect or an inverse spin galvanic effect. As the function of STT magnetic tunnel junctions is well known in the art, it will not be further described here.

As with write currents in conventional STT MTJ devices, in devices using SOT switching mechanisms, the direction of torque applied by the spin current is dependent on the direction of the current flow in the SOT channel. In other words, the direction of current flow through the conductor adjacent to the free region determines the direction of torque that is applied to the free region. Accordingly, a free region of the present disclosure may be able to be switched between two stable states based on torque applied by current flowing though the neighboring SOT channel in one direction or the other. In some embodiments, the free region may be able to be switched between two stable magnetic states based on the torque applied by a current flowing in either direction through the adjacent conductor. The magnetic state of the free region may also be switched by the torque resulting from both an STT current by applying an electrical current through MTJ bit and a spin current injected from one or more SH materials by applying an electrical current through one or more SH materials.

In some embodiments, the torque applied by the spin current (e.g., SOT current) alone is used to switch the free region into a particular magnetic state, whereas in other embodiments, the spin current works as an “assist” to reduce the magnitude of an STT write current required to switch the magnetic state of the free region, where the STT write current travels through the entirety of the MTJ stack to produce a spin polarized tunneling current between the free region and fixed region. Reading of data stored by the MTJ stack is accomplished as in a conventional STT MTJ device. For example, a read current, having a magnitude less than that of the STT critical current of the MTJ stack, is applied to the MTJ stack to sense the resistance of the MTJ stack. As a person of ordinary skill in the art would recognize, there are many techniques that may be used to detect or sense the resistance of the MTJ stack. In some embodiments, the resistance sensed based on the read current can be compared with a reference resistance to determine the state of the free region. In some embodiments, a self-referenced read operation is performed where the resistance through the MTJ is sensed, then the MTJ is written (or reset) so that the free region is in a known state, then the resistance is sensed again and compared with the resistance originally sensed. The original state of the free region can then be determined based on whether the resistance has changed based on the write or reset operation. In still other embodiments, a mid-point reference read operation may be performed.

For the sake of brevity, conventional techniques related to semiconductor processing may not be described in detail herein. The exemplary embodiments may be fabricated using known lithographic processes. The fabrication of integrated circuits, microelectronic devices, micro-electro-mechanical devices, microfluidic devices, and photonic devices involves the creation of several layers or regions (e.g., comprising one or more layers) of materials that interact in some fashion. One or more of these regions may be patterned so that various regions of the layer have different electrical or other characteristics, which may be interconnected within the region or to other regions to create electrical components and circuits. These regions may be created by selectively introducing or removing various materials. The patterns that define such regions are often created by lithographic processes. For example, a layer of photoresist is applied onto a layer overlying a wafer substrate. A photo mask (containing clear and opaque areas) is used to selectively expose the photoresist by a form of radiation, such as ultraviolet light, electrons, or x-rays. Either the photoresist exposed to the radiation, or not exposed to the radiation, is removed by the application of the developer. An etch may then be employed/applied whereby the layer (or material) not protected by the remaining resist is patterned. Alternatively, an additive process can be used in which a structure is built up using the photoresist as a template.

In one aspect, the disclosed embodiments relate to, among other things, methods of manufacturing a magnetoresistive stack having one or more electrically conductive electrodes, vias, or conductors on either side of a magnetic material stack. As described in further detail below, the magnetic material stack may include many different regions of material, where some of these regions include magnetic materials, whereas others do not. In one embodiment, the methods of manufacturing include sequentially depositing, growing, sputtering, evaporating, and/or providing (which may be referred to collectively herein as “depositing”) regions which after further processing (e.g., etching) form a magnetoresistive stack.

In some embodiments, the disclosed magnetoresistive stacks may be formed between a top electrode/via/line and a bottom electrode/via/line, both of which may permit access to the stack by allowing for connectivity (e.g., electrical) to circuitry and other elements of the magnetoresistive device. Between the electrodes/vias/lines are multiple regions, including at least one fixed region, at least one free region, and one or more intermediate regions that form a tunnel barrier between the fixed region and the free region. In some embodiments, the one or more intermediate regions may be made of dielectric materials. Each of the fixed region and the free region may include, among other things, a plurality of ferromagnetic layers. In some embodiments, the fixed region may include a synthetic antiferromagnetic (SAF) structure. In some embodiments, a top electrode (and/or) bottom electrode may be eliminated, and a bit line may be formed on top of the stack. Additionally, each stack may be disposed adjacent to an SOT channel. The SOT channel carries the switching current that imparts a spin-orbit torque to the free region during write and reset operations. In at least one embodiment, the electrodes/vias/lines of the magnetoresistive stacks may comprise a write line. In other embodiments, a magnetoresistive stack is formed between a top electrode/via/line and a bottom electrode/via/line and further is adjacent to an SOT channel, which may be independently connected to a current source. In such embodiments, the magnetoresistive device may be referred to as a “three-terminal” magnetoresistive device.

In one aspect, the present disclosure may relate to SOT MRAM random access memory (SOT MRAM) devices and/or non-volatile logic devices and methods of manufacturing and using such devices. However, the embodiments of the current disclosure may be applicable to other types of devices, including but not limited to spin-transfer-torque (STT) devices.

As alluded to previously, a magnetoresistive stack used in a memory device (e.g., MRAM) includes at least one non-magnetic layer (for example, at least one dielectric layer or a non-magnetic yet electrically conductive layer) disposed between a “fixed” magnetic region (hereinafter referred to as a “fixed region”) and a “free” magnetic region (hereinafter referred to as a “free region”), each including one or more layers of ferromagnetic materials. Information may be stored in the magnetoresistive memory stack by switching, programming, and/or controlling the direction of magnetization vectors (e.g., magnetization direction) in the magnetic layer(s) of the free region. The direction of the magnetization vectors of the free region may be switched and/or programmed (for example, through spin-orbit-torque (SOT) or spin-transfer-torque (STT)) by applying a write signal (e.g., one or more current pulses) to the magnetoresistive memory stack (e.g., directing one or more current pulses through the magnetoresistive stack by STT switching, or along an SOT channel by SOT switching, etc.). In contrast, the magnetization vectors in the magnetic layers of a fixed region are magnetically fixed in a predetermined direction. When the magnetization vectors of the free region adjacent to the non-magnetic layer (e.g., a dielectric layer) are in the same direction as the magnetization vectors of the fixed region adjacent to the non-magnetic layer, the magnetoresistive memory stack has a first magnetic state having a first electrical resistance (e.g., a low resistance state). Conversely, when the magnetization vectors of the free region adjacent to the non-magnetic layer are opposite the direction of the magnetization vectors of the fixed region adjacent to the non-magnetic layer, the magnetoresistive memory stack has a second magnetic state having a second electrical resistance (e.g., a high resistance state). The magnetic state of the magnetoresistive memory stack is determined or read based on the resistance of the stack in response to a read current (e.g., by directing a read current through the stack).

It should be noted that, although exemplary embodiments in the disclosure are described and/or illustrated herein in the context of MTJ stacks/structures, embodiments may also be implemented in giant magnetoresistive (GMR) stacks/structures where a conductor (e.g., copper) is disposed between two ferromagnetic regions/layers/materials. Indeed, embodiments of the present disclosure may also be employed in connection with other types of magnetoresistive stacks (and/or structures) wherein such stacks include a fixed region, a free region, an intermediate region, etc. For the sake of brevity, the discussions and illustrations will not be repeated specifically in the context of GMR or other magnetoresistive stacks/structures—but such discussions and illustrations are to be interpreted as being entirely applicable to GMR and other stacks/structures.

As magnetic memory devices (e.g., MRAM) advance towards smaller process nodes to, for example, increase density, individual MTJ bit sizes must laterally shrink to accommodate tighter pitch and space between bits. However, as the size and/or aspect ratio of the MTJ bit decreases, the energy barrier between the two magnetic states of the free region of the MTJ also may decrease. As the energy barrier decreases, however, the data retention and/or thermal stability of the MTJ bit also may decrease or otherwise become compromised. Typically, the decrease in energy barrier of the MTJ bit may be corrected or mitigated by increasing the magnetic anisotropy or magnetic moment of the free region by, e.g., altering its composition, material, and/or dimensions. However, doing so may also raise the critical current of the MTJ bit under certain instances. MTJ bits with high critical currents undergo a greater amount of periodic damage and degeneration during write and/or reset operations, for example, in spin-transfer-torque (STT) magnetoresistive devices. In the case of in-plane magnetic tunnel junctions, the existence of demagnetization field effect in relation to critical currents may also decrease the switching efficiency (due to an increase in the critical current). Furthermore, as the MTJ bit sizes become smaller, electrical encroachment effect in the MTJ bits becomes larger, leading to a decreased magnetoresistance ratio (MR) and an increased MTJ resistance in the low resistance state, and an increased STT-switching voltage.

In some embodiments, the present disclosure relates to devices and methods for attaining high energy barrier and switching efficiency in smaller-sized MTJ bits (e.g., MTJ bits with relatively smaller dimensions), by manipulating the shape, composition, and/or dimensions of such MTJ bits. Further, in some embodiments, the present disclosure relates to devices and methods for attaining high cycling endurance of MTJ bits, by utilizing a spin-orbit-torque (SOT) channel to switch the MTJ bits. The scope of the current disclosure, however, is defined by the attached claims, and not by any characteristics of the resulting device or method.

U.S. Pat. No. 11,127,896 titled “SHARED SPIN-ORBIT-TORQUE WRITE LINE IN A SPIN-ORBIT-TORQUE MRAM,” U.S. Provisional Patent Application No. 63/586,315 titled “MAGNETORESISTIVE DEVICE AND METHOD OF MANUFACTURING THE SAME,” U.S. Provisional Patent Application No. 63/565,964 titled “ANTI-FUSE AND FUSE IN MAGNETORESISTIVE DEVICE,” and U.S. Provisional Patent Application No. 63/634,183 titled “CONFIGURATION BIT WITH SPIN-ORBIT TORQUE” are related to SOT MRAM devices and are incorporated herein by reference in their entireties.

In the conventional technologies related to SOT MRAM devices with a perpendicular anisotropy free layer, the necessity of external magnetic field or another symmetry breaking measure limits the practical application of SOT devices. If ferromagnetic material is included in an SOT channel, switching direction of free layer (e.g., antiparallel (AP) to parallel (P) or vice versa) by a certain direction of write current can depend on the magnetization direction of the ferromagnetic material. If the magnetization direction of the SOT channel for each bit in the MRAM array is different from each other, write operations cannot be controlled by the direction of write current. If the SOT channel within a bit has multi-magnetic domains, the switching efficiency is reduced.

Further, application of an external in-plane magnetic field can be disadvantageous because, although the field can be generated by a current flowing through lines in semiconductor devices, such a method can take up space and consumes energy and is thus not scalable. Magnetic dipole coupling to an in-plane fixed ferromagnetic layer in close proximity to the free layer also presents some issues. For example, the energy barrier, which determines data retention performance, is reduced as a result of the in-plane bias field. In addition, the statistical distribution of this in-plane stray field can create an additional source of bit-to-bit distribution of writing performance. Furthermore, the additional in-plane fixed layer increases the overall thickness of the MTJ stack, which can make it more difficult to achieve a tight pitch in high-density memory arrays.

Structural asymmetry by laterally varying layer thickness may be a symmetry breaking measure. However, it is not manufacturable on an industry level wafer size. Chiral asymmetry by a vertical composition gradient in the free layers requires certain materials (TbCo), which do not have sufficient tolerance against standard BEOL process temperature (˜400° C.). When magnetic asymmetry using an exchange-biased free layer is implemented, simultaneously achieving exchange bias (EB), large SOT efficiency, and sizeable perpendicular magnetic anisotropy (PMA) in the same material system is difficult and constrains the range of material options available for such devices. In addition, there is large bit-to-bit distribution of the EB because EB is non-uniform and depends on the local orientation of the Néel vector (e.g., the domain structure) within the antiferromagnetic (AFM) layer. This makes it difficult to achieve uniform switching characteristics in devices whose size is smaller than the typical AFM domain size, (e.g., ˜200 nm).

Unconventional SOT channel materials (RuOₓ or Mn₃Sn) with the specific crystal asymmetry orientation may be another symmetry breaking measure. However, to get uniform deterministic switching, all of the SOT channels in an array must have the same specific crystal orientation, which requires single crystal-like seed layer or highly crystalline oriented seed layer under the SOT channel, thus posing additional challenges.

The embodiments of the current disclosure eliminates or minimizes the challenges or shortcomings of the conventional technology discussed above, by using certain materials (e.g., Co, Fe, CoFe, CoFeB, or their alloy) within the SOT channel instead of conventional heavy metal, leading to a break in the inversion symmetry, field free switching for perpendicular free layer, and low switching current. By placing antiferromagnetic layer adjacent to the SOT channel and exerting exchange bias to the SOT channel, the embodiments in the current disclosure fixes the in-plane magnetization direction of the SOT channel to one direction for all bits in an MRAM array to achieve precise and uniform write operation in the array, with a countermeasure to avoid write current loss. There are multiple ways for achieving the countermeasure, including removing the antiferromagnetic layer just below (or just above) the free layer, using high-resistance antiferromagnetic materials, and others.

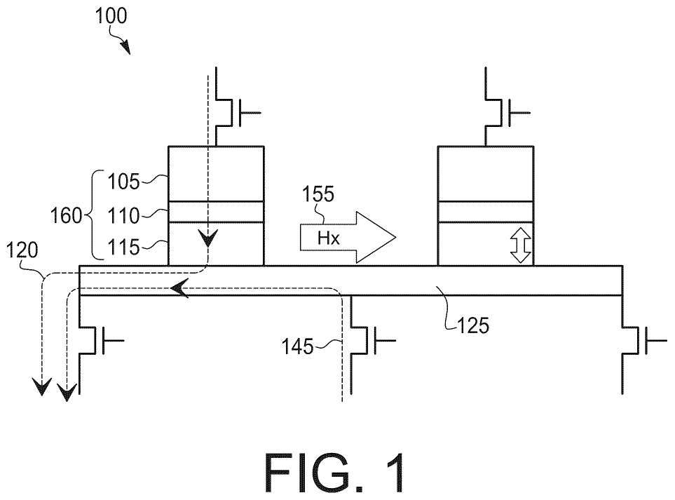

FIG. 1 depicts a conventional spin-orbit-torque magnetoresistive random access memory (SOT MRAM) device. The conventional SOT-MRAM device 100 includes perpendicular anisotropy magnetic tunnel junction (pMTJ). SOT-MRAM device 100 includes fixed magnetic layer 105, tunnel barrier 110, free magnetic layer 115, and SOT channel 125. Write current 145 is applied through the SOT channel 125 from a current source to switch the magnetic state of the free magnetic layer 115. Read current 120 is applied through the MTJ stack 160 to determine the state of the “bit” represented by the MTJ stack 160. The SOT channel 125 includes heavy metal (e.g., platinum, tungsten, tantalum, or their alloys), topological insulator, or transition metal dichalcogenide, which are not ferromagnetic materials. The direction of the write current 145 along the SOT channel 125 defines the free magnetic layer 115 magnetization direction (e.g., up or down) and hence the memory state of “0” or “1”. To get deterministic switching with perpendicular anisotropy in the free magnetic layer 115, it is necessary to externally apply an in-plane magnetic field 155 to break the inversion symmetry. The external field can be replaced by other symmetry breaking measures including, for example, magnetic dipole coupling to an in-plane fixed ferromagnetic layer in close proximity to the free magnetic layer 115, structural asymmetry by laterally varying layer thickness, chiral asymmetry by using a vertical composition gradient in the free magnetic layer 115, magnetic asymmetry by using an exchange-biased the free magnetic layer 115, unconventional SOT channel 125 materials (e.g., RuOₓ or Mn₃Sn) with the specific crystal orientation, etc. Exchange bias occurs in bilayers of ferromagnetic and antiferromagnetic regions. Antiferromagnetic thin film may cause a shift in the magnetization curve of a ferromagnetic film. The exchange bias phenomenon is useful to fix the magnetization direction of ferromagnetic films. The direction of the exchange bias may be set by annealing in the presence of an applied magnetic field.

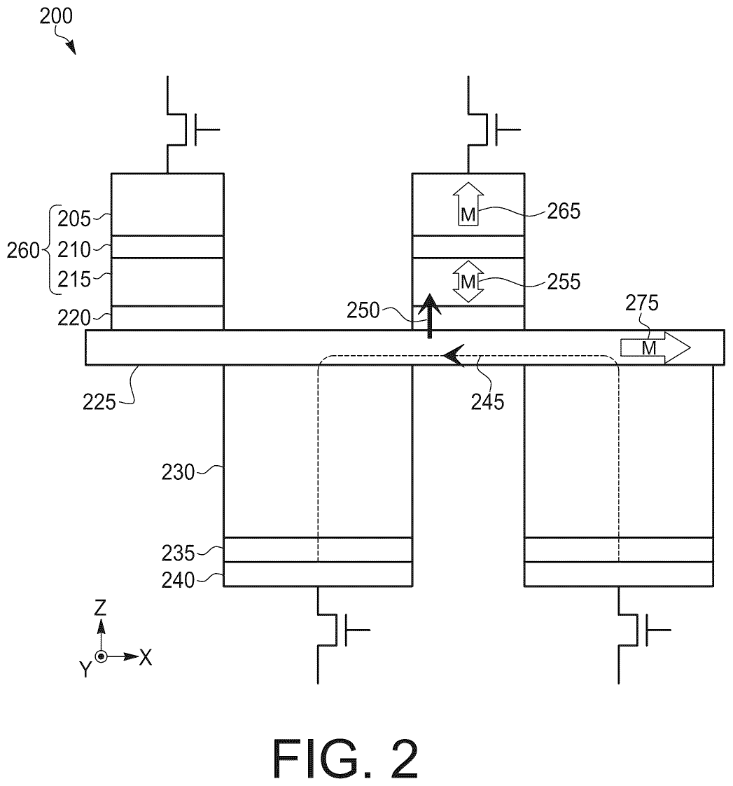

FIG. 2 depicts an exemplary SOT MRAM device, according to one or more embodiments. SOT MRAM device 200 may include fixed magnetic layer 205, tunnel barrier 210, and free magnetic layer 215 that form MTJ stack 260. The SOT MRAM device 200 may also include insertion layer 220. The tunnel barrier 210 may be disposed between the fixed magnetic layer 205 and the free magnetic layer 215. The insertion layer 220 may be disposed between the free magnetic layer 215 and the SOT channel 225. Throughout this disclosure, the MTJ stack 260 and the insertion layer 220 together may be referred to as a magnetoresistive device. The SOT MRAM device 200 may also include SOT channel 225, antiferromagnetic layer 230, template layer 235, and seed layer 240. In some embodiments, one consolidated seed layer (not shown) may be used instead of two layers (e.g., the template layer 235 and the seed layer 240), which means the consolidated seed layer may include the functions of both the template layer 235 and the seed layer 240. The MTJ stack 260 and the insertion layer 220 may be disposed on one side of the SOT channel 225, and the antiferromagnetic layer 230 may be disposed on another side of the SOT channel 225 (e.g., on the opposite side of the SOT channel 225 from the MTJ stack 260), the antiferromagnetic layer 230 being in contact with the SOT channel 225. The antiferromagnetic layer 230 may be disposed above template layer 235 and seed layer 240. The SOT MRAM device 200 may create write current 245 and spin current 250. Arrow 255 represents the magnetization direction of the free magnetic layer 215, which may be changed based on the direction of the write current 245 in the SOT channel 225. Arrow 265 represents the magnetization direction of the fixed magnetic layer 205, which is fixed and does not change. Arrow 275 represents the magnetization direction of the SOT channel 225, which can be set to either direction.

The SOT channel 225 may include ferromagnetic metal with in-plane magnetization. The material(s) for the SOT channel 225 may include cobalt (Co), iron (Fe), boron (B), cobalt-iron (CoFe), cobalt-iron-boron (CoFeB), or their alloys. The SOT channel 225 may have a thickness between 3 nm and 6 nm. In another embodiment, the SOT channel 225 may have a thickness of 4 nm. The antiferromagnetic layer 230 may be disposed adjacent to the SOT channel 225, which exerts exchange bias to the SOT channel 225. The antiferromagnetic layer 230 may include platinum-manganese (PtMn) or iridium-manganese (IrMn). The antiferromagnetic layer 230 may have a thickness between 10 nm and 40 nm. In another embodiment, the antiferromagnetic layer 230 may have a thickness of 20 nm. As shown in FIG. 2, removing all or most of the antiferromagnetic layer 230 directly below the free magnetic layer 215 and instead placing all or most of the antiferromagnetic layer 230 between the MTJ stacks 260 (or the free magnetic layers 215 thereof) on the other side of the SOT channel 225 constrains the write current 245 to flow through the SOT channel 225. The insertion layer 220 may be disposed between the free magnetic layer 215 and the SOT channel 225 to prevent exchange coupling between the free magnetic layer 215 and the SOT channel 225. The insertion layer 220 may consist of titanium (Ti), platinum (Pt), or ruthenium (Ru). The insertion layer 220 may include a thickness between 1 nm and 4 nm. In another embodiment, the insertion layer 220 may include a thickness of 3 nm.

The SOT MRAM device 200 as described above, does not need an external field or other symmetry breaking measure to get deterministic switching of perpendicular anisotropy free magnetic layer 215. The SOT MRAM device 200 may achieve a low switching current by a factor of 3 to 5 compared with conventional heavy metal SOT channels. The SOT MRAM device 200 may achieve a low switching current based on the particular spin polarization of the generated spin current that has not only a conventional Y-component but also an unconventional Z-component. The Z-component does not depend on crystal orientation but depends on the magnetization direction of the SOT channel 225. In addition, the crystal orientation of the SOT channel 225 becomes less of a concern. All bits in an MRAM array achieve precise and uniform write operation controlled solely by the direction of the write current 245. This is due to the SOT channel 225 magnetizations for all bits in an MRAM array are aligned to the same direction by exchange bias (EB). One or more embodiments of the present disclosure, including the SOT MRAM device 200, use EB applied to the SOT channel 225 and not the free magnetic layer 215. Thereby, non-uniformity of EB does not cause bit-to-bit distribution of switching performance. One or more embodiments of the present disclosure, including the SOT MRAM device 200, reduce joule heating along the write current 245 and improve energy efficiency and reliability of the MRAM array. Conventional designs using high resistance SOT channels generate a massive amount of joule heating, which degrades energy efficiency, magnetic properties of the MTJs, and reliability of MAM arrays. One or more embodiments of the present disclosure, including the SOT MRAM device 200, utilize the antiferromagnetic layer 230 to decrease resistance and hence joule heating along the write current 245. An advantage of the SOT MRAM device 200 is the non-use of exotic materials, keeping the manufacturing costs down.

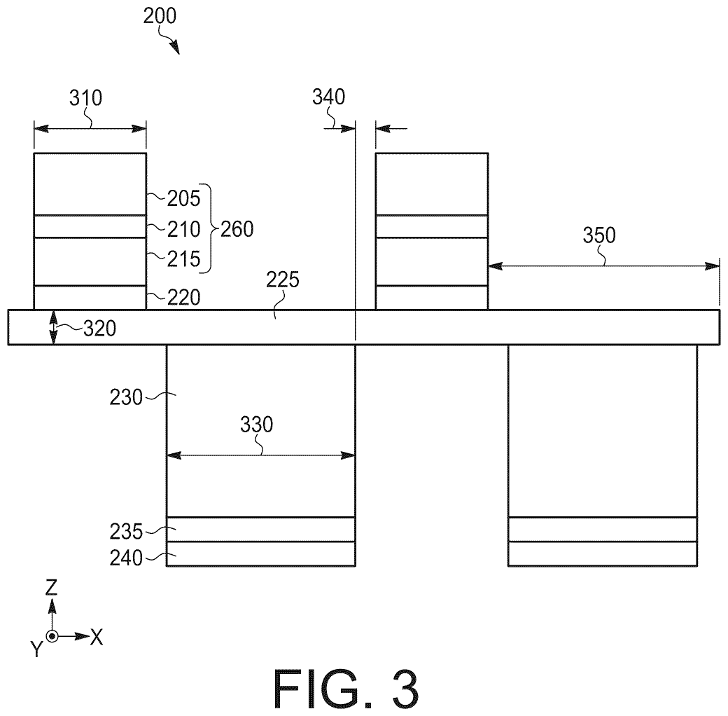

FIG. 3 depicts an exemplary SOT MRAM device and its dimensions, according to one or more embodiments. The SOT MRAM device illustrated in FIG. 3 is same as the SOT MRAM device 200 previously described in FIG. 2. In FIG. 3, certain components of the SOT MRAM device 200 are not shown for brevity and ease of explanation. The SOT MRAM device 200, as described in FIG. 3, may include the following dimensions. The region including the MTJ stack 260 and the insertion layer 220 (or the MTJ stack 260) may have a width 310 between 10 nm and 100 nm. In some embodiments, the width 310 may be between 20 nm and 70 nm. The SOT channel 225 may have a thickness 320 between 3 nm and 6 nm and a width along the direction orthogonal to the page that is equal to or larger than the width 310 of the MTJ stack 260 and is equal to or smaller than 1.6 times the width 310 of the MTJ stack 260, or that is equal to or larger than the width 310 of the MTJ stack 260 and is equal to or smaller than 1.2 times the width 310 of the MTJ stack 260, or that is equal to the width 310 of the MTJ stack 260. For example, if the width 310 is 100 nm, SOT channel 225 may have a width between 100 nm and 160 nm, a width between 100 nm and 120 nm, or a width of approximately 100 nm. The antiferromagnetic layer 230 (and the template layer 235 and the seed layer 240 disposed below the antiferromagnetic layer 230) may have a length 330 that is equal to or larger than the width 310 of the MTJ stack 260 and is equal to or smaller than 4 times the width 310 of the MTJ stack 260. For example, if the width 310 is 100 nm, the antiferromagnetic layer 230 may have a length 330 between 100 nm and 400 nm. The lateral distance 340 between an edge of the antiferromagnetic layer 230 laterally facing the MTJ stack 260 and an edge of the MTJ stack 260 laterally facing the antiferromagnetic layer 230 may be less than or equal to approximately 20 nm. In one embodiment, the lateral distance 340 between an edge of the antiferromagnetic layer 230 laterally facing the MTJ stack 260 and an edge of the MTJ stack 260 laterally facing the antiferromagnetic layer 230 may be 0 nm. In some embodiments, an edge of the antiferromagnetic layer 230 laterally facing the MTJ stack 260 and an edge of the MTJ stack 260 laterally facing the antiferromagnetic layer 230 may laterally overlap by up to 5 nm. The distance 350 between a distal end of the SOT channel 225 and an edge of the free magnetic layer 215 laterally facing the distal end of the SOT channel 225 may be larger than the width 310 of the MTJ stack 260 (e.g., if the width 310 is 100 nm, or longer than 100 nm). In some embodiments, the distance 350 may be larger than 2 times the width 310 of the MTJ stack 260 (e.g., if the width 310 is 100 nm, or larger than 200 nm). The distal end of the SOT channel 225 may be designed to be far from the free magnetic layer 215 to avoid the in-plane stray field, which degrades data retention performance and field immunity of writing.

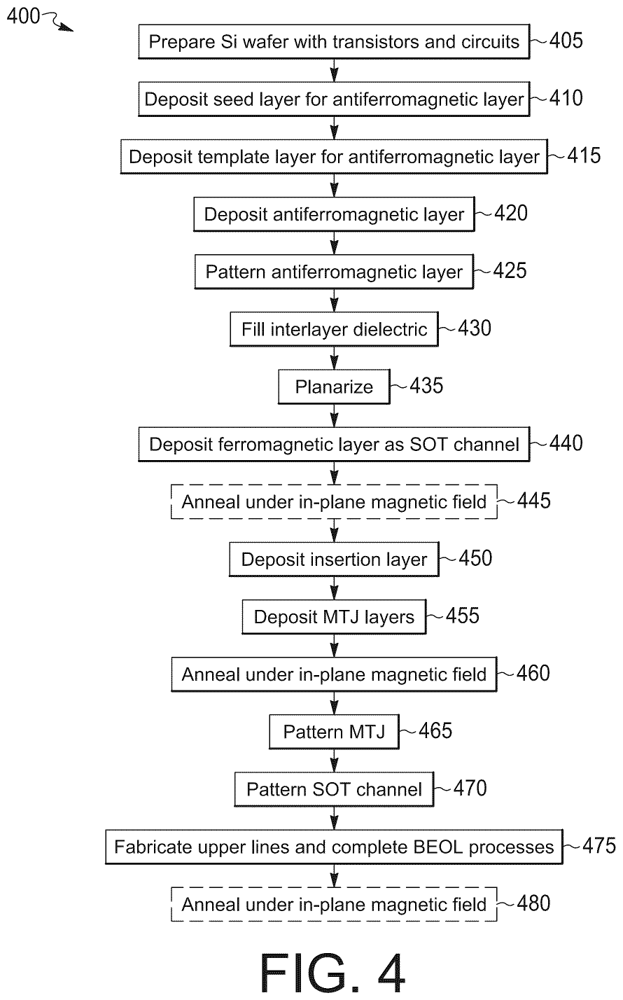

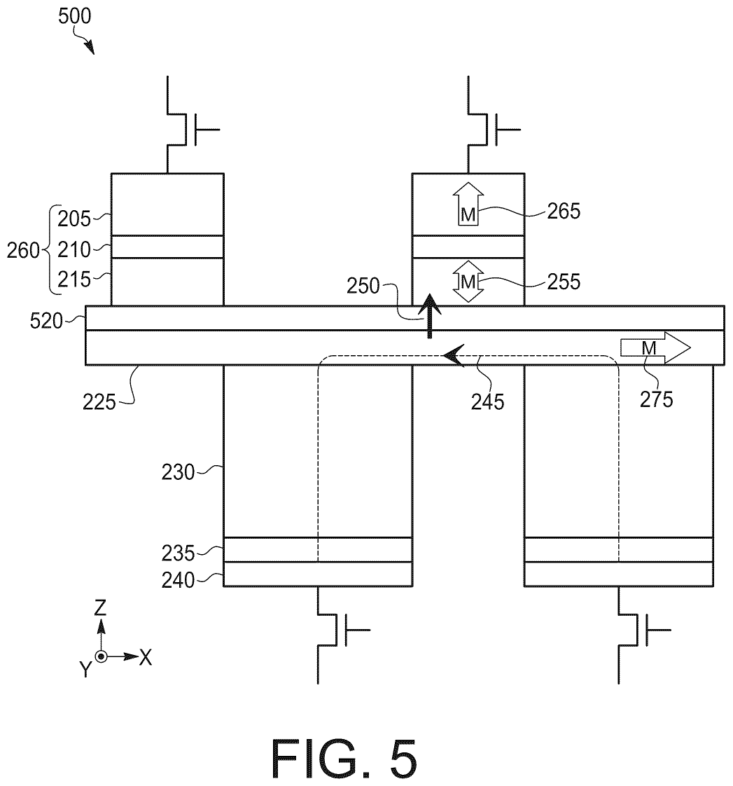

FIG. 4 depicts a flow diagram for manufacturing an exemplary SOT MRAM device, according to one or more embodiments. For example, method 400 may illustrate the manufacturing process for the SOT MRAM device 200 described in FIG. 2, or the SOT MRAM device 500 described in FIG. 5. Method 400 may start at step 405 by preparing a silicon (Si) wafer with transistors and circuits. Next, step 410 may include depositing a seed layer 240 for an antiferromagnetic layer 230. Materials for the seed layer 240 may include one or more of tantalum-nitrogen (TaN), aluminum (Al), or tantalum (Ta). The thickness of the seed layer 240 may be between 1 nm and 5 nm. Step 415 may include depositing a template layer 235 over the seed layer 240 for the antiferromagnetic layer 230. Materials for the template layer 235 may include one or more of nickel-iron (NiFe) or ruthenium (Ru). The thickness of the template layer 235 may be between 1 nm and 4 nm. Additional information corresponding to seed layer 240 and template layer 235 (including, e.g., fabrication method, material(s) of choice, enclosed structures/regions/layers, advantages and purposes, and other relevant information) may be found in U.S. Pat. No. 6,801,415, which is incorporated herein by reference in its entirety. Next, step 420 may include depositing an antiferromagnetic layer 230 over the template layer 235. Step 425 may include patterning the antiferromagnetic layer 230 to the desired dimensions discussed above in reference to FIGS. 2-3. Next, step 430 may include depositing an interlayer dielectric material. Step 435 may include planarizing the interlayer dielectric material to expose a surface (e.g., a top surface) of the antiferromagnetic layer 230. Next, step 440 may include depositing a ferromagnetic layer to form an SOT channel 225. Step 450 may include depositing an insertion layer 220 above the SOT channel 225. Next, step 455 may include depositing an MTJ stack 260 (or depositing MTJ layers), the MTJ layers including a free magnetic layer 215, a fixed magnetic layer 205, and a tunnel barrier 210 disposed between the fixed magnetic layer 205 and the free magnetic layer 215. The insertion layer 220 may be disposed adjacent to the free magnetic layer 215, and the fixed magnetic layer 205 is formed above the tunnel barrier 210 and the free magnetic layer 215.

Next, step 460 may include performing an annealing process under an in-plane magnetic field. The annealing process may be performed at a temperature between 250 and 350 degrees Celsius, for a duration of about 1 hour, and under a magnetic field strength between 1 and 10 kilo oersteds (kOe). In one embodiment, the anneal process may be performed under a magnetic field strength of approximately 5 kOe. Step 465 may include patterning the MTJ stack 260 (and the insertion layer 220) to the desired dimensions discussed above in reference to FIGS. 2-3, followed by step 470 of patterning the SOT channel 225 to the desired dimensions discussed above in reference to FIGS. 2-3. Step 475 may include forming upper lines and completing back end of line (BEOL) processes. Step 460 of the method 400 may be replaced by step 445 or step 480, by performing an annealing process under the in-plane magnetic field at different times within the method 400. In one embodiment, step 445, step 460, or step 480, may only be performed once during the method 400. The annealing process may be performed between step 440 and step 450, between step 455 and step 465, or after step 475. Upon the completion of the method 400, the SOT channel 225 magnetization for all bits in the memory array (e.g., MRAM array) may be aligned to the same direction.

FIG. 5 depicts an exemplary SOT MRAM device, according to one or more embodiments. Certain components of SOT MRAM device 500 may be similar to the corresponding components of the SOT MRAM device 200 described in FIG. 2 and FIG. 3. For brevity, the description for those aspects of the SOT MRAM device 500 (e.g., the width 310 of the MTJ stack 260, the length 330 of the antiferromagnetic layer 230, the lateral distance 340 between an edge of the antiferromagnetic layer 230 laterally facing the MTJ stack 260 and an edge of the MTJ stack 260 laterally facing the antiferromagnetic layer 230, the distance 350 between a distal end of the SOT channel 225 and an edge of the free magnetic layer 215 laterally facing the distal end of the SOT channel 225, the SOT channel 225 materials, the SOT channel 225 thickness 320, SOT channel 225 width, the antiferromagnetic layer 230 materials, the template layer 235 materials, the seed layer 240 materials, the magnetization direction 255, the magnetization direction 265, the magnetization direction 275, the write current 245, and the spin current 250) will not repeated. The SOT MRAM device 500 may include MTJ stack 260 (e.g., fixed magnetic layer 205, tunnel barrier 210, and free magnetic layer 215). The SOT MRAM device 500 may also include insertion layer 520 to span a length of SOT channel 225. The insertion layer 520 may cover one side of the whole SOT channel 225 to prevent degradation of the SOT channel 225 materials for a longer duration of use. This is achieved by preventing oxidation of ferromagnetic metal in the SOT channel 225 from interlayer dielectrics. The end result may be improved reliability of the resultant MRAM devices.

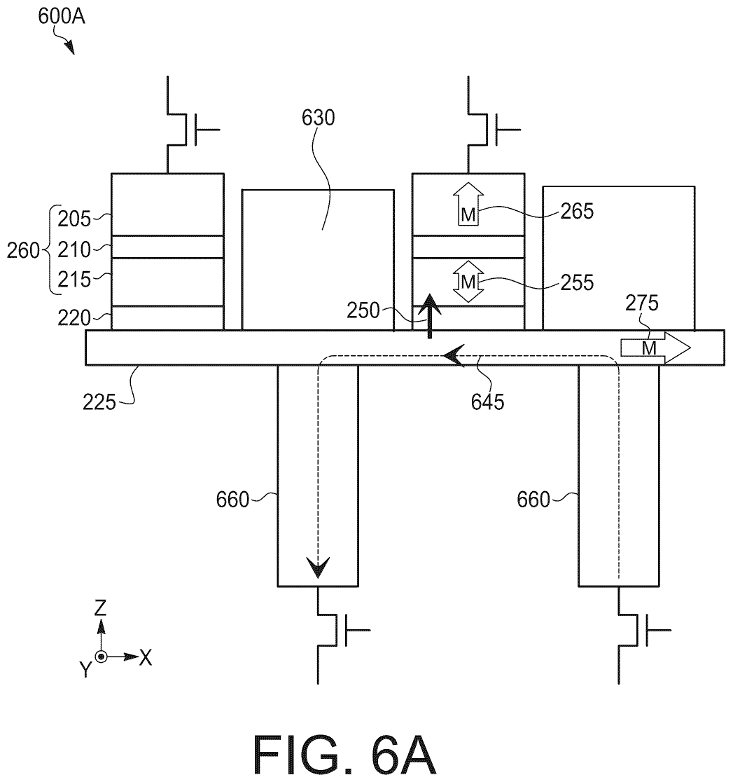

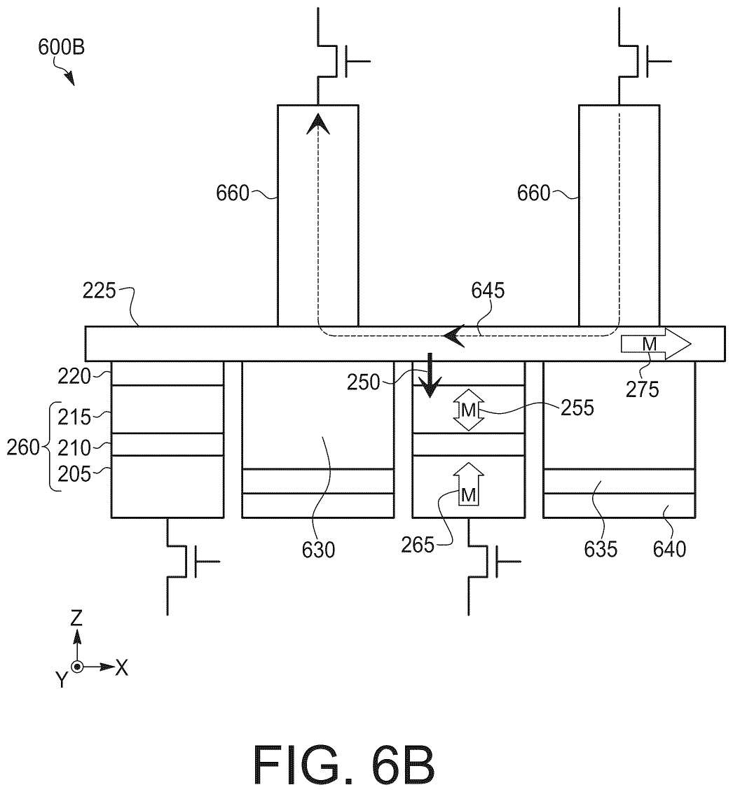

FIGS. 6A and 6B depict an exemplary SOT MRAM device, according to one or more embodiments. Certain components of the SOT MRAM device 600A may be similar to the corresponding components of the SOT MRAM device 200 described in FIG. 2 and FIG. 3. For brevity, the description for those aspects of the SOT MRAM device 600A (e.g., the width 310 of the MTJ stack 260, the length 330 of the antiferromagnetic layer 230, the lateral distance 340 between an edge of the antiferromagnetic layer 230 laterally facing the MTJ stack 260 and an edge of the MTJ stack 260 laterally facing the antiferromagnetic layer 230, the distance 350 between a distal end of the SOT channel 225 and an edge of the free magnetic layer 215 laterally facing the distal end of the SOT channel 225, the SOT channel 225 materials, the SOT channel 225 thickness 320, SOT channel 225 width, the antiferromagnetic layer 230 materials, the template layer 235 materials, the seed layer 240 materials, the magnetization direction 255, the magnetization direction 265, the magnetization direction 275, the write current 245, and the spin current 250) will not repeated. The SOT MRAM device 600A may include MTJ stack 260 (e.g., fixed magnetic layer 205, tunnel barrier 210, and free magnetic layer 215) and insertion layer 220 as described in FIG. 2. The SOT MRAM device 600A may also include antiferromagnetic layer 630. In contrast with the configuration depicted in FIGS. 2, 3, and 5, the antiferromagnetic layer 630 may be disposed on the same side of the SOT channel 225 as the MTJ stack 260, effectively placing the antiferromagnetic layer 630 between the MTJ stacks 260. The SOT MRAM device 600A may further include metal via 660 disposed on the opposite side of the SOT channel 225 from the antiferromagnetic layer 630. The antiferromagnetic layer 630 may be disposed on a first side of the SOT channel 225 and the metal via 660 may be disposed on a second side, opposite of the first side, of the SOT channel 225. Further, as illustrated in FIG. 6A, each metal via 660 and a corresponding antiferromagnetic layer 630 are disposed above the same vertical axis, but they are on the opposite sides relative to the SOT channel 225. Placing the antiferromagnetic layer 630 between the MTJ stacks 260 on the same side of the SOT channel 225 exerts an exchange bias to the SOT channel 225. Write current 645 is constrained through the metal via 660 and the SOT channel 225.

The SOT MRAM device 600A as described above, does not need an external field or other symmetry breaking measure to get deterministic switching of perpendicular anisotropy free magnetic layer 215. The SOT MRAM device 600A may achieve a low switching current by a factor of 3 to 5 compared with conventional heavy metal SOT channels. The SOT MRAM device 600A may achieve a low switching current based on the particular spin polarization of the generated spin current that has not only a conventional Y-component but also an unconventional Z-component. The Z-component does not depend on crystal orientation but depends on the magnetization direction of the SOT channel 225. In addition, the crystal orientation of the SOT channel 225 becomes less of a concern. All bits in an MRAM array achieve precise and uniform write operation controlled solely by the direction of the write current 645. This is due to the SOT channel 225 magnetizations for all bits in an MRAM array are aligned to the same direction by exchange bias (EB). One or more embodiments of the present disclosure, including the SOT MRAM device 600A, use EB applied to the SOT channel 225 and not the free magnetic layer 215. Thereby, non-uniformity of EB does not cause bit-to-bit distribution of switching performance. One or more embodiments of the present disclosure, including the SOT MRAM device 600A, reduce joule heating along the write current 645 and improve energy efficiency and reliability of the MRAM array. Conventional designs using high resistance SOT channels generate a massive amount of joule heating, which degrades energy efficiency, magnetic properties of the MTJs, and reliability of MRAM arrays. One or more embodiments of the present disclosure, including the SOT MRAM device 600A, utilize the antiferromagnetic layer 630 to decrease resistance and hence joule heating along the write current 645. An advantage of the SOT MRAM device 200 is the non-use of exotic materials, keeping the manufacturing costs down.

SOT MRAM device 600B illustrated in FIG. 6B. SOT MRAM may include the same components of the SOT MRAM device 600A. The SOT MRAM device 600B may also have the same technical benefits and advantages of the SOT MRAM device 600A. However, the SOT MRAM device 600B may include an inverted orientation relative to the SOT MRAM device 600A. The SOT MRAM device 600B may also include template layer 635 and see layer 640, where the template layer 635 is disposed between the seed layer 640 and the antiferromagnetic layer 630.

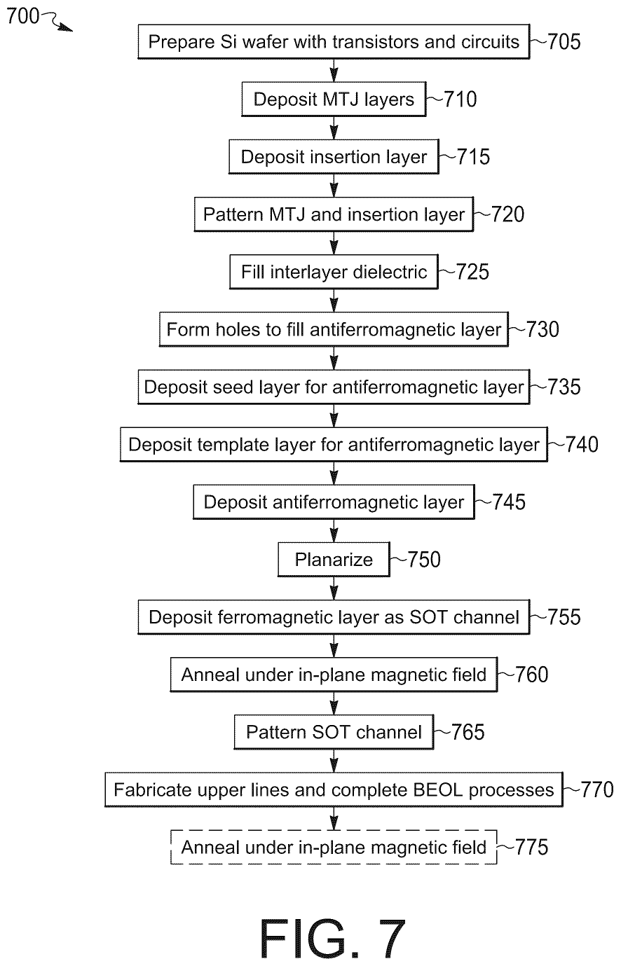

FIG. 7 depicts a flow diagram for manufacturing an exemplary SOT MRAM device, according to one or more embodiments. For example, method 700 may illustrate the manufacturing process for the SOT MRAM device 600B described in FIG. 6B. Method 700 may start at step 705 by preparing a silicon (Si) wafer with transistors and circuits. Next, step 710 may include depositing an MTJ stack 260 (or depositing MTJ layers), the MTJ stack 260 including fixed magnetic layer 205, free magnetic layer 215, and tunnel barrier 210 disposed between the fixed magnetic layer 205 and the free magnetic layer 215. In the MTJ stack 260, the fixed magnetic layer 205 may be deposited first, followed by the tunnel barrier 210 and the free magnetic layer 215. Step 715 may include depositing an insertion layer 220 above the free magnetic layer 215. The insertion layer 220 may be disposed adjacent to the free magnetic layer 215. Next, step 720 may include patterning the MTJ stack 260 (and the insertion layer 220) to the desired dimensions discussed above in reference to FIGS. 2-3. Step 725 may include depositing an interlayer dielectric material. Next, step 730 may include forming holes or cavities for later forming an antiferromagnetic layer 630. Step 735 may include depositing a seed layer 640 for an antiferromagnetic layer 630. Materials for the seed layer 240 may include one or more of TaNₓ, Al, or Ta. The thickness of the seed layer 240 may be between 1 nm and 5 nm. Step 740 may include depositing a template layer 635 over the seed layer 640 for the antiferromagnetic layer 630. Materials for the template layer 235 may include one or more of NiFe or Ru. The thickness of the template layer 235 may be between 1 nm and 4 nm. Additional information corresponding to seed layer 640 and template layer 635 (including, e.g., fabrication method, material(s) of choice, enclosed structures/regions/layers, advantages and purposes, and other relevant information) may be found in U.S. Pat. No. 6,801,415, which is incorporated herein by reference in its entirety. In some embodiments, steps 735 and 740 may be combined into a single step of depositing a consolidated seed layer, which is configured to perform the functions of one or both of the seed layer 240 and the template layer 235.

Next, step 745 may include depositing an antiferromagnetic layer 630 over the template layer 635. Step 750 may include planarizing the antiferromagnetic layer 630 to level a top surface of the insertion layer 220 and a top surface of the antiferromagnetic layer 630. Next, step 755 may include depositing a ferromagnetic layer to form an SOT channel 225. Step 760 may include performing an annealing process under an in-plane magnetic field. The annealing process may be performed at a temperature between 250 and 350 degrees Celsius, for a duration of about 1 hour, and under a magnetic field strength between 1 and 10 kilo oersteds (kOe). In one embodiment, the annealing process may be performed under a magnetic field strength of approximately 5 kOe. Step 765 may include patterning the SOT channel 225 to the desired dimensions discussed above in reference to FIGS. 2-3. Next, step 770 may include forming upper lines and completing back end of line (BEOL) processes. Step 760 of method 700 may be replaced by step 775, by performing an annealing process under the in-plane magnetic field at different times within method 700. However, step 760 or step 775 may only be performed once during method 700. The annealing process may be performed between step 755 and step 765 or after step 770. Upon the completion of method 700, the SOT channel 225 magnetization for all bits in the memory array (e.g., MRAM array) may be aligned to the same direction.

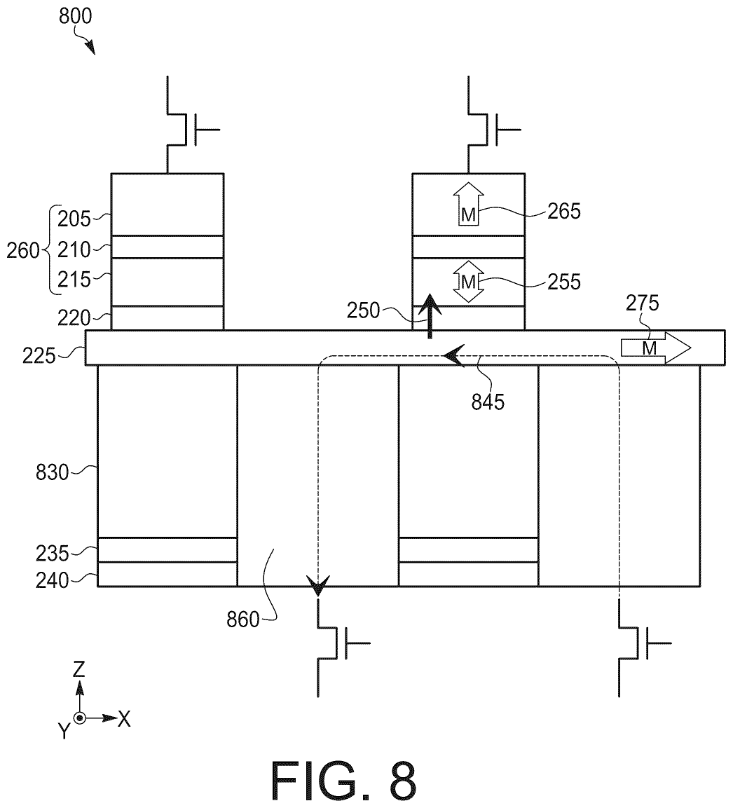

FIG. 8 depicts an exemplary SOT MRAM device, according to one or more embodiments. Certain components of the SOT MRAM device 800 may be similar to the corresponding components of the SOT MRAM device 200 as described in FIG. 2 and FIG. 3. For brevity, the description for those aspects of the SOT MRAM device 800 (e.g., the width 310 of the MTJ stack 260, the length 330 of the antiferromagnetic layer 230, the lateral distance 340 between an edge of the antiferromagnetic layer 230 laterally facing the MTJ stack 260 and an edge of the MTJ stack 260 laterally facing the antiferromagnetic layer 230, the distance 350 between a distal end of the SOT channel 225 and an edge of the free magnetic layer 215 laterally facing the distal end of the SOT channel 225, the SOT channel 225 materials, the SOT channel 225 thickness 320, SOT channel width, the antiferromagnetic layer 230 materials, the template layer 235 materials, and the seed layer 240 materials) will not repeated. The SOT MRAM device 800 may include MTJ stack 260 (e.g., fixed magnetic layer 205, tunnel barrier 210, and free magnetic layer 215) and insertion layer 220. The SOT MRAM device 800 may include high resistance antiferromagnetic layer 830 and metal via 860. Write current 845 may be constrained to the metal via 860 and the SOT channel 225. The high resistance antiferromagnetic layer 830 may be disposed directly below a corresponding MTJ stack 260, but on the other side of the SOT channel 225 from the MTJ stack 260. The high resistance antiferromagnetic layer 830 and the MTJ stack 260 may be placed on the same vertical axis as shown in FIG. 8, but they may be on opposite sides of the SOT channel 225. Each metal via 860 may be disposed between two (e.g., a pair of) neighboring high resistance antiferromagnetic layers 830. The metal via 860 and the high resistance antiferromagnetic layer 830 may be disposed on a same side of the SOT channel 225, opposite from the site on which the MTJ stack 260 and the insertion layer 220 are disposed. The metal via 860 disposed on one side of (e.g., underneath, as shown in FIG. 8) the SOT channel 225 except below the free magnetic layer 215 reduces joule heating.

The high resistance antiferromagnetic layer 830 differs from the antiferromagnetic layer 230, as described in FIG. 2, in that the high resistance antiferromagnetic layer 830 uses highly resistive materials, such as MnSiN₂, BiFeO₃ (perovskite oxides), other perovskite oxides, CuFeS₂ (zinc-blende compound), other zinc-blende compounds, LiMnAs, or Heusler compounds. Resistivity of the high resistance antiferromagnetic layer 830 may be more than 50 times higher than that of the SOT channel 225 material to avoid write current 845 flowing through the high resistance antiferromagnetic layer 830. The high resistance antiferromagnetic layer 830 may have a thickness between 10 nm and 40 nm. In one embodiment, the high resistance antiferromagnetic layer 830 may include a thickness of approximately 20 nm. The insertion layer 220 is disposed between the SOT channel 225 and the free magnetic layer 215 to prevent exchange coupling between the SOT channel 225 and the free magnetic layer 215.

The SOT MRAM device 800 as described above, does not need an external field or other symmetry breaking measure to get deterministic switching of perpendicular anisotropy free magnetic layer 215. The SOT MRAM device 800 may achieve a low switching current by a factor of 3 to 5 compared with conventional heavy metal SOT channels. The SOT MRAM device 800 may achieve a low switching current based on the particular spin polarization of the generated spin current that has not only a conventional Y-component but also an unconventional Z-component. The Z-component does not depend on crystal orientation but depends on the magnetization direction of the SOT channel 225. In addition, the crystal orientation of the SOT channel 225 becomes less of a concern. All bits in an MRAM array achieve precise and uniform write operation controlled solely by the direction of the write current 845. This is due to the SOT channel 225 magnetizations for all bits in an MRAM array are aligned to the same direction by exchange bias (EB). One or more embodiments of the present disclosure, including the SOT MRAM device 800, use EB applied to the SOT channel 225 and not the free magnetic layer 215. Thereby, non-uniformity of EB does not cause bit-to-bit distribution of switching performance. One or more embodiments of the present disclosure, including the SOT MRAM device 800, reduce joule heating along the write current 845 and improve energy efficiency and reliability of the MRAM array. Conventional designs using high resistance SOT channels generate a massive amount of joule heating, which degrades energy efficiency, magnetic properties of the MTJs, and reliability of MRAM arrays. In the SOT MRAM device 800, the use of large metal vias 860 decreases resistance and hence joule heating along the write current 845.

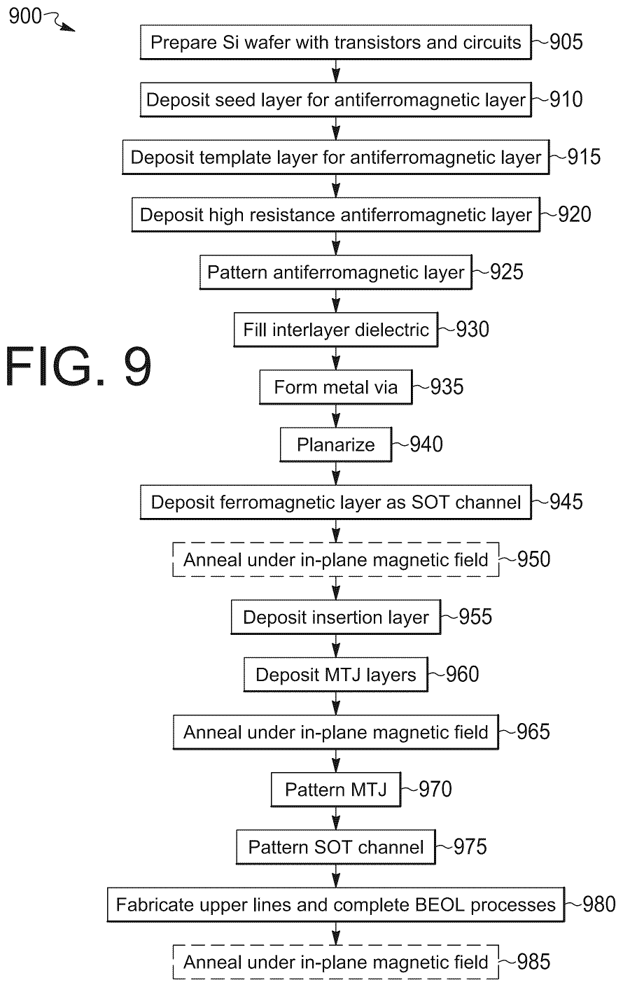

FIG. 9 depicts flow diagram for manufacturing an exemplary SOT MRAM device, according to one or more embodiments. For example, method 900 may illustrate the manufacturing process for the SOT MRAM device 800 described in FIG. 8. Method 900 may start at step 905 by preparing a silicon (Si) wafer with transistors and circuits. Next, step 910 may include depositing a seed layer 240 for a high resistance antiferromagnetic layer 830. The seed layer 240 may differ from those described in FIG. 4. In some embodiments, the seed layer 240 may be the same as the seed layer 240 described in reference to FIG. 4. Step 915 may include depositing a template layer 235 over the seed layer 240 for the high resistance antiferromagnetic layer 830. The template layer 235 may differ from those described in FIG. 4. In some embodiments, the template layer 235 may be the same as the template layer 235 described in reference to FIG. 4. Next, step 920 may include depositing a high resistance antiferromagnetic layer 830 over the template layer 235. Step 925 may include patterning the high resistance antiferromagnetic layer 830 (along with the seed layer 240 and the template layer 235) to the desired dimensions discussed above in reference to FIG. 8. Next, step 930 may include depositing (e.g., filling the area with) an interlayer dielectric material. Step 935 may include forming a metal via 860. A metal via 860 may be disposed between two (e.g., a pair of) neighboring high resistance antiferromagnetic layers 830. Next, step 940 may include planarizing the metal via 860 and the interlayer dielectric material to expose a surface (e.g., a top surface) of the high resistance antiferromagnetic layer 830. Next, step 945 may include depositing a ferromagnetic layer to form an SOT channel 225. Step 955 may include depositing an insertion layer 220 above the SOT channel 225. Next, step 960 may include depositing an MTJ stack 260 (or depositing MTJ layers), the MTJ stack 260 including fixed magnetic layer 205, free magnetic layer 215, and tunnel barrier 210 disposed between the fixed magnetic layer 205 and the free magnetic layer 215. The insertion layer 220 may be disposed adjacent to the free magnetic layer 215.

Next, step 965 may include performing an annealing process under an in-plane magnetic field. The annealing process conditions may differ from those described in FIG. 4. In some embodiments, the annealing process conditions may be the same as the annealing process described in reference to FIG. 4. Step 970 may include patterning the MTJ stack 260 (and the insertion layer 220), followed by step 975 of patterning the SOT channel 225. Step 980 may include forming upper lines and completing back end of line (BEOL) processes. Step 965 of method 900 may be replaced by step 950 or step 985, performing an annealing process under the in-plane magnetic field at different times within method 900. However, step 950, step 965, or step 985, may only be performed once during method 900. The annealing process may be performed between step 945 and step 955, between step 960 and step 970, or after step 980. Upon the completion of method 900, the SOT channel 225 magnetization for all bits in the memory array (e.g., MRAM array) may be aligned to the same direction.

Other embodiments of the disclosure will be apparent to those skilled in the art from consideration of the specification and practice of the invention disclosed herein. It is intended that the specification and examples be considered as exemplary only, with a true scope and spirit of the disclosure being indicated by the following claims.

In one embodiment, the techniques described herein relate to a magnetoresistive memory, including: a plurality of magnetoresistive devices, wherein each magnetoresistive device includes a fixed magnetic layer, a free magnetic layer, a tunnel barrier disposed between the fixed and free magnetic layers, and an insertion layer disposed below the free magnetic layer, wherein the fixed magnetic layer is formed above the free magnetic layer; a plurality of antiferromagnetic layers, wherein each antiferromagnetic layer is disposed above a seed layer; and a spin-orbit-torque (SOT) channel, wherein the SOT channel is disposed between the plurality of magnetoresistive devices and the plurality of antiferromagnetic layers.

Various embodiments may comprise, without limitation: wherein the SOT channel includes at least one of cobalt (Co), iron (Fe), boron (B), or an alloy thereof; wherein the SOT channel has a width between 10 nm and 160 nm; wherein each antiferromagnetic layer includes at least one of platinum-manganese (PtMn) or iridium-manganese (IrMn); wherein each antiferromagnetic layer has a length between 10 nm and 400 nm; wherein the insertion layer includes at least one of titanium (Ti), platinum (Pt), or ruthenium (Ru); wherein each antiferromagnetic layer is disposed substantially between a pair of magnetoresistive devices of the plurality of magnetoresistive devices and on an opposite side of the SOT channel from the plurality of magnetoresistive devices, and wherein a lateral distance between an edge of at least one magnetoresistive device and an edge of at least one antiferromagnetic layer is less than or equal to approximately 20 nm or the edge of the at least one magnetoresistive device and the edge of the at least one antiferromagnetic layer overlap by up to 5 nm; wherein a distance between an edge of the free layer and an edge of the SOT channel is greater than a width of each magnetoresistive device; wherein the insertion layer is disposed between the free magnetic layer and the SOT channel, wherein the insertion layer spans a length of the SOT channel; wherein each antiferromagnetic layer is disposed directly below a corresponding magnetoresistive device of the plurality of magnetoresistive devices; wherein the magnetoresistive memory further includes: a plurality of metal vias, wherein each metal via is disposed between at least two of the plurality of antiferromagnetic layers, and wherein each magnetoresistive device and a corresponding antiferromagnetic layer are disposed about a same axis.

In one embodiment, the techniques described herein relate to a magnetoresistive memory, including: a plurality of magnetoresistive devices, wherein each magnetoresistive device includes a fixed magnetic layer, a free magnetic layer, a tunnel barrier disposed between the fixed and free magnetic layers, and an insertion layer disposed adjacent the free magnetic layer; a plurality of antiferromagnetic layers, wherein the each antiferromagnetic layer is disposed between two of the plurality of magnetoresistive devices; a plurality of metal vias; and a spin-orbit-torque (SOT) channel, wherein the plurality of magnetoresistive devices and the plurality of antiferromagnetic layers are disposed on a first side of the SOT channel and the plurality of metal vias are disposed on a second side of the SOT channel opposite the first side.

Various embodiments may comprise, without limitation: wherein each metal via and a corresponding antiferromagnetic layer are disposed about the same axis.

In one embodiment, the techniques described herein relate to a method of forming a magnetoresistive memory including: depositing a seed layer; depositing an antiferromagnetic layer over the seed layer; patterning the antiferromagnetic layer; depositing an interlayer dielectric material; planarizing the interlayer dielectric material to expose a surface of the antiferromagnetic layer; depositing a ferromagnetic layer, wherein the ferromagnetic layer forms a spin-orbit-torque (SOT) channel; depositing an insertion layer; and depositing a magnetoresistive device layer, wherein the magnetoresistive device layer includes: a fixed magnetic layer, a free magnetic layer, a tunnel barrier disposed between the fixed and free magnetic layers, and an insertion layer disposed adjacent the free magnetic layer, wherein the fixed magnetic layer is formed above the free magnetic layer.

Various embodiments may comprise, without limitation: upon depositing the magnetoresistive device layer, performing an annealing process under an in-plane magnetic field; patterning the magnetoresistive device layer; and patterning the SOT channel; upon depositing the ferromagnetic layer and prior to depositing the insertion layer, performing an annealing process under an in-plane magnetic field; patterning the magnetoresistive device layer; patterning the SOT channel; and performing an annealing process under an in-plane magnetic field; performing an annealing process under an in-plane magnetic field, wherein the annealing process is performed at a temperature between approximately 250 and 350 degrees Celsius, for a duration of approximately one hour, and with a magnetic field strength between approximately 1 and 10 kilo oersteds (kOe); wherein the seed layer includes at least one of tantalum-nitrogen (TaN), aluminum (Al), or tantalum (Ta); depositing a template layer over the seed layer before depositing the antiferromagnetic layer, wherein the template layer includes at least one of nickel-iron (NiFe) or ruthenium (Ru).

What is claimed is:

1. A magnetoresistive memory, comprising:
a plurality of magnetoresistive devices, wherein each magnetoresistive device includes a fixed magnetic layer, a free magnetic layer, a tunnel barrier disposed between the fixed and free magnetic layers, and an insertion layer disposed below the free magnetic layer, wherein the fixed magnetic layer is formed above the free magnetic layer;
a plurality of antiferromagnetic layers, wherein each antiferromagnetic layer is disposed above a seed layer; and
a spin-orbit-torque (SOT) channel, wherein the SOT channel is disposed between the plurality of magnetoresistive devices and the plurality of antiferromagnetic layers.

2. The magnetoresistive memory of claim 1, wherein the SOT channel includes at least one of cobalt (Co), iron (Fe), boron (B), or an alloy thereof.

3. The magnetoresistive memory of claim 1, wherein the SOT channel has a width between 10 nm and 160 nm.

4. The magnetoresistive memory of claim 1, wherein each antiferromagnetic layer includes at least one of platinum-manganese (PtMn) or iridium-manganese (IrMn).

5. The magnetoresistive memory of claim 1, wherein each antiferromagnetic layer has a length between 10 nm and 400 nm.

6. The magnetoresistive memory of claim 1, wherein the insertion layer includes at least one of titanium (Ti), platinum (Pt), or ruthenium (Ru).

7. The magnetoresistive memory of claim 1, wherein each antiferromagnetic layer is disposed substantially between a pair of magnetoresistive devices of the plurality of magnetoresistive devices and on an opposite side of the SOT channel from the plurality of magnetoresistive devices, and wherein a lateral distance between an edge of at least one magnetoresistive device and an edge of at least one antiferromagnetic layer is less than or equal to approximately 20 nm or the edge of the at least one magnetoresistive device and the edge of the at least one antiferromagnetic layer overlap by up to 5 nm.

8. The magnetoresistive memory of claim 1, wherein a distance between an edge of the free layer and an edge of the SOT channel is greater than a width of each magnetoresistive device.

9. The magnetoresistive memory of claim 1, wherein the insertion layer is disposed between the free magnetic layer and the SOT channel, wherein the insertion layer spans a length of the SOT channel.

10. The magnetoresistive memory of claim 1, wherein each antiferromagnetic layer is disposed directly below a corresponding magnetoresistive device of the plurality of magnetoresistive devices.

11. The magnetoresistive memory of claim 1, further including:
a plurality of metal vias, wherein each metal via is disposed between at least two of the plurality of antiferromagnetic layers, and
wherein each magnetoresistive device and a corresponding antiferromagnetic layer are disposed about a same axis.

12. A magnetoresistive memory, comprising:
a plurality of magnetoresistive devices, wherein each magnetoresistive device includes a fixed magnetic layer, a free magnetic layer, a tunnel barrier disposed between the fixed and free magnetic layers, and an insertion layer disposed adjacent the free magnetic layer;
a plurality of antiferromagnetic layers, wherein the each antiferromagnetic layer is disposed between two of the plurality of magnetoresistive devices;
a plurality of metal vias; and
a spin-orbit-torque (SOT) channel, wherein the plurality of magnetoresistive devices and the plurality of antiferromagnetic layers are disposed on a first side of the SOT channel and the plurality of metal vias are disposed on a second side of the SOT channel opposite the first side.

13. The magnetoresistive memory of claim 12, wherein each metal via and a corresponding antiferromagnetic layer are disposed about a same axis.

14. A method of forming a magnetoresistive memory comprising:
depositing a seed layer;
depositing an antiferromagnetic layer over the seed layer;
patterning the antiferromagnetic layer;
depositing an interlayer dielectric material;
planarizing the interlayer dielectric material to expose a surface of the antiferromagnetic layer;
depositing a ferromagnetic layer, wherein the ferromagnetic layer forms a spin-orbit-torque (SOT) channel;
depositing an insertion layer; and
depositing a magnetoresistive device layer, wherein the magnetoresistive device layer includes:
a fixed magnetic layer, a free magnetic layer, a tunnel barrier disposed between the fixed and free magnetic layers, and an insertion layer disposed adjacent the free magnetic layer, wherein the fixed magnetic layer is formed above the free magnetic layer.

15. The method of claim 14, further comprising:
upon depositing the magnetoresistive device layer, performing an annealing process under an in-plane magnetic field;
patterning the magnetoresistive device layer; and
patterning the SOT channel.

16. The method of claim 14, further comprising:
upon depositing the ferromagnetic layer and prior to depositing the insertion layer, performing an annealing process under an in-plane magnetic field.

17. The method of claim 14, further comprising:
patterning the magnetoresistive device layer;
patterning the SOT channel; and
performing an annealing process under an in-plane magnetic field.

18. The method of claim 14, further comprising:
performing an annealing process under an in-plane magnetic field, wherein the annealing process is performed at a temperature between approximately 250 and 350 degrees Celsius, for a duration of approximately one hour, and with a magnetic field strength between approximately 1 and 10 kilo oersteds (kOe).

19. The method of claim 14, wherein the seed layer includes at least one of tantalum-nitrogen (TaN), aluminum (Al), or tantalum (Ta).

20. The method of claim 14, further comprising:
depositing a template layer over the seed layer before depositing the antiferromagnetic layer, wherein the template layer includes at least one of nickel-iron (NiFe) or ruthenium (Ru).
